(19) United States
(12) Patent Application Publication
(10) Pub. No.: US 2010/0104751 A1
(43) Pub. Date: Apr. 29, 2010

(54) EVAPORATING APPARATUS, EVAPORATING METHOD AND MANUFACTURING METHOD OF EVAPORATING APPARATUS

(75) Inventor: Kenji Sudou, Hyogo (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/525,093

(22) PCT Filed: Jan. 30, 2008
(86) PCT No.: PCT/JP2008/051395

§ 371 Date: Jul. 30, 2009

(30) Foreign Application Priority Data
Feb. 1, 2007 (JP) 2007-023402

(51) Int. Cl. C23C 16/44; C23C 16/00

(52) U.S. Cl. 427/248.1; 118/726

(57) ABSTRACT

An evaporating apparatus includes: a plurality of vapor deposition sources for respectively vaporizing different film forming materials accommodated therein; a plurality of blowing devices for blowing off film forming materials vaporized from the vapor deposition sources through blowing openings; and one or more partition walls for separating the adjacent blowing devices. The one or more partition walls are installed such that relationships of a gap G between each partition wall and the substrate, a height T from each blowing opening to a top surface of each partition wall, a thickness D of each partition wall and a distance E from a center position of each vapor deposition source to a center position of each partition wall satisfy an inequality of E<(G+T)×D/2G. Further, an internal pressure of the processing chamber is controlled to be about 0.01 Pa or less.

### TECHNICAL FIELD

The present invention relates to an evaporating apparatus, an evaporating method and a manufacturing method of the evaporating apparatus. In particular, the present invention relates to contamination within the evaporating apparatus.

### BACKGROUND ART

Widely employed in a manufacturing process of an electronic device such as a flat panel display or the like is an evaporating method for forming a film on a target object by adhering gas molecules, which are generated as a result of vaporizing a preset film forming material, to the target object. Among various types of devices manufactured by using such an evaporating technology, an organic EL display is particularly known to be superior to a liquid crystal display for the reason of its self-luminescence, high reaction speed, low power consumption and so forth. Accordingly, increasing demands for the organic EL display are expected from now on, and it is attracting high attention in the field of manufacture of the flat panel display. Thus, the evaporating technology employed in the manufacture of the organic EL display is deemed to be very important.

The evaporating technology getting attention under such a technical background is implemented by an evaporating apparatus. In a conventional evaporating apparatus, one vapor deposition source is included in one processing chamber (for example, see Patent Document 1). Therefore, in the conventional evaporating apparatus, vaporized molecules discharged from the vapor deposition source pass through a mask and then adhere to a predetermined position of the target object, so that it is possible to perform a desirable film formation on the target object. For this end, there is a need of one processing chamber to form a single layer of a film on the target object.

Patent Document 1: Japanese Patent Laid-open Publication No. 2000-282219

### DISCLOSURE OF THE INVENTION

### Problems to Be Solved by the Invention

However, in view of the foregoing, if there is a need of one processing chamber to form a single layer of a film, there is a need of a plurality of processing chambers to form a plurality of film layers on a target object and thus a footprint is increased. As a result, a factory becomes large-scaled and there is a high likelihood that a contaminant is adhered onto the target object during transfer of the target object.

Meanwhile, in order to solve this problem, it can be conceived that a plurality of thin films is consecutively formed on a target object by installing a plurality of vapor deposition sources in one processing chamber and adhering film forming molecules vaporized by each vapor deposition source onto the target object. However, in this case, there is likelihood that the film forming molecules discharged from one vapor deposition source are mixed with the film forming molecules discharged from the adjacent vapor deposition source (i.e., cross-contamination) and thus a film quality of each layer may be deteriorated.

In order to solve this problem, the present invention provides an evaporating apparatus, an evaporating method and a manufacturing method of the evaporating apparatus for consecutively forming a plurality of film layers in the same processing chamber while reducing the cross-contamination.

### Means for Solving the Problems

That is, in accordance with an aspect of the present invention, there is provided an evaporating apparatus for performing a film forming process on a target object by a vapor deposition in a processing chamber, the apparatus including: a plurality of vapor deposition sources, each accommodating a film forming material and vaporizing the accommodated film forming material; a plurality of blowing devices, each being connected with each of the vapor deposition sources and each blowing device having a blowing opening and blowing off each film forming material vaporized from each of the vapor deposition sources through the blowing opening; and one or more partition walls disposed between adjacent blowing devices among the plurality of blowing devices, for separating the adjacent blowing devices.

Here, the term “vaporization” or “evaporation” implies not only the phenomenon that a liquid is converted into a gas but also a phenomenon that a solid is directly converted into a gas without becoming a liquid (i.e., sublimation).

In this way, the film forming materials (film forming molecules) vaporized from the plurality of the vapor deposition sources are respectively blown off from the blowing openings of the plurality of the blowing devices installed in the same processing chamber. Here, installed between the adjacent blowing devices are one or more partition walls for respectively separating the adjacent blowing devices. By these partition walls, the vaporized film forming materials can be consecutively formed into the films on the target object in the same processing chamber while preventing the film forming material discharged from each blowing opening from crossing each partition wall and flying to the adjacent blowing opening (i.e., preventing a cross-contamination). Accordingly, it is possible to avoid a deterioration of a film quality of each layer which is caused by that the film forming molecules vaporized from one vapor deposition source are mixed with the film forming molecules vaporized from the adjacent vapor deposition source (i.e., a cross-contamination).

In addition, with this configuration, since the film forming processes are consecutively performed in the same processing chamber, it is possible to reduce a contaminant adhered onto the target object during transfer. Accordingly, it is possible to maintain properties of each layer favorable by preventing a cross-contamination, and to increase a controllability for an energy interface and to lower an energy barrier by reducing the number of contaminants adhered to the target object. As a result, a luminous intensity (luminance) of an organic EL device can be improved. Further, by consecutively performing the film forming processes on the target object in the same processing chamber, a footprint can be reduced.

Moreover, the film forming material accommodated in each vapor deposition source may be an organic EL film forming material or an organic metal film forming material, and the evaporating apparatus may be an apparatus for forming any one of an organic EL film and an organic metal film on the target object by using the organic EL film forming material or the organic metal film forming material as an organic material.

Further, the plurality of blowing devices may have the same shape and may be arranged in parallel to each other at a same distance therebetween, and the one or more partition walls may have the same shape, and may be equally distant from the adjacent blowing devices and arranged in parallel to each other at a same distance between the adjacent blowing devices.

Furthermore, each surface of the partition wall facing a surface of the adjacent blowing device may be larger than the surface of the adjacent blowing device. With this configuration, the partition walls can prevent the film forming material blown off from the blowing opening of each blowing device from flying toward the adjacent blowing device.

Further, the one or more partition walls may be arranged so as to satisfy two conditions: among the film forming material radially diffused from a blowing opening provided at the adjacent blowing device, a film forming material with a longest flight distance traveling in a straight line to the target object without being blocked by each partition wall has an arriving position which is closer to the blowing opening that blows off the film forming material with the longest flight distance than to a position on the target object equally distant from the adjacent blowing devices, and the longest flight distance of the film forming material is shorter than a mean free path of the film forming material.

In this way, the arrangement positions of the respective partition walls are specified to satisfy the two conditions. By satisfying a first condition, i.e., an arriving position of a film forming material with a longest flight distance traveling in a straight line to the target object without being blocked by each partition wall is closer to the blowing opening that blows off the film forming material with the longest flight distance than to a position on the target object equally distant from the adjacent blowing devices, there occurs little contamination which is caused by that the film forming materials blown off from the adjacent blowing openings are mixed therewith. Accordingly, it is possible to consecutively form films having desired properties on the target object only with the film forming molecules blown off from the respective blowing openings.

Further, by satisfying a second condition, i.e., the longest flight distance of the film forming material is shorter than a mean free path of the film forming material, all the film forming molecules blown off from each blowing opening and radially diffused can reach the target object without collision while flying in a space of the processing chamber. Accordingly, it is possible to uniformly form a good quality film on the target object.

At this time, as illustrated in FIG. 6, the mean free path depends on a pressure. That is, the mean free path is longer as the pressure becomes lower whereas the mean free path is shorter as the pressure becomes higher. Furthermore, in case that the films are formed consecutively on the target object by slowly moving the target object around the blowing opening, if each partition wall and the target object have a too small gap therebetween, there is likelihood that the target object on the moving collides against the partition wall. Therefore, it is desirable that an internal pressure of the processing chamber is equal to or less than about 0.01 Pa so that the film forming material with the longest flight distance reaches the target object while maintaining the gap between each partition wall and the target object such that the target object on the moving does not collide against the partition wall.

Furthermore, each of the partition walls may be arranged such that relationships of a gap G between each partition wall and the target object, a height T from each blowing opening to a top surface of each partition wall, a thickness D of each partition wall and a distance E from a center position of each vapor deposition source to a center position of each partition wall satisfy: E<(G+T)×D×G/2.

As illustrated in FIG. 9, the film forming molecules discharged from a blowing opening Op travel in a straight line in a radial shape. The reason why the film forming molecules travel in a straight line is that pressures of the inside (inside of a pipe) and the outside (inside of a chamber) of the blowing opening Op are, for example, in the range from about 72 Pa to about 73 Pa and about 4×10⁻³ Pa respectively, so that the film forming molecules are discharged at one time by a pressure difference of about 10⁴ times from the inside under high-pressure toward the outside of the blowing opening through the blowing opening Op formed in a slot shape having 200 mm×3 mm. The film forming molecules discharged from the blowing opening Op by such a pressure difference energetically “travel in a straight line.” Therefore, if a condition, i.e., the arriving position of the film forming material with the longest flight distance traveling in a straight line to the target object without being blocked by each partition wall (a distance X from the blowing opening to the arriving position of the film forming material with the longest flight distance in an X-axis direction) is shorter than the position of the target object equally distant from the adjacent blowing device (a distance E from the blowing opening to a center position of the adjacent partition wall in the X-axis direction) is satisfied, most of the film forming molecules blown off from each blowing opening Op are reach within a radial diffusion area and are not mixed with the film forming molecules blown off from the adjacent blowing opening Op.

This condition can be expressed by the following inequality.

E>X (1)

If a position relationship between a gap G from each partition wall to the target object and a height T from each blowing opening to a top surface of each partition wall and a thickness D of each partition wall is applied to the inequality (1), an inequality of E<(G+T)×D×G/2 is derived as a result.

Further, in accordance with another aspect of the present invention, there is provided an evaporating method for performing a film forming process on a target object by a vapor deposition in a processing chamber, the method including: vaporizing each of film forming materials accommodated in each of vapor deposition sources; blowing off each film forming material vaporized from each vapor deposition source through an blowing opening of each blowing device connected with each vapor deposition source; and consecutively forming films on a target object with the vaporized film forming materials while preventing the film forming materials blown off from respective blowing openings from crossing each partition wall and flying to adjacent blowing openings by using one or more partition walls disposed between the adjacent blowing devices among the plurality of blowing devices, for separating the adjacent blowing devices.

Furthermore, in accordance with still another aspect of the present invention, a method for manufacturing an evaporating apparatus which performs a film forming process on a target object by a vapor deposition method in a processing chamber, the method including: arranging a plurality of blowing devices in parallel to each other at a same distance therebetween inside the processing chamber, each blowing device being connected with each of vapor deposition sources for vaporizing a film forming material respectively, each blowing device blowing off the film forming material vaporized from each vapor deposition source through an blowing opening; and arranging the one or more partition walls to be equally distant from the adjacent blowing devices and in parallel to each other at a same distance.

Here, the one or more partition walls may be arranged by determining a gap from each partition wall to the target object, a height of each partition wall, a thickness of each partition wall, and a position of each partition wall respectively so as to satisfy two conditions, i.e., the arriving position of the film forming material, among the film forming material radially diffused from the blowing opening of the adjacent blowing device, with the longest flight distance traveling in a straight line to the target object without being blocked by each partition wall is disposed in the vicinity of the blowing opening discharging the film forming material with the longest flight distance rather than at a position on the target object equally distant from the adjacent blowing device; and the longest flight distance of the film forming material is shorter than the mean free path of the film forming material.

In accordance with the above descriptions, it is possible to manufacture an evaporating apparatus in which by using one or more partition walls for respectively separating the adjacent blowing devices, the films can be consecutively formed on the target object with the vaporized film forming materials while preventing the film forming materials discharged from each blowing opening from crossing each partition wall and flying toward the adjacent blowing opening.

### EFFECT OF THE INVENTION

As stated above, in accordance with the present invention, it is possible to consecutively form a plurality of film layers in the same processing chamber while reducing cross-contamination.

### BRIEF DESCRIPTION OF THE DRAWINGS

FIG. 1 is a perspective view of major components of an evaporating apparatus in accordance with an embodiment of the present invention;

FIG. 2 is a view for explaining a film formed by 6-layer consecutive film forming process in accordance with this embodiment;

FIG. 3 is a view of an experimental apparatus, which is simplified from the evaporating apparatus in accordance with this embodiment, for use in Experiment 1;

FIG. 4 is a graph showing a result of the Experiment 1;

FIG. 5 is a view for explaining a film forming state in the Experiment 1;

FIG. 6 is a table showing a dependency of a mean free path on a pressure;

FIG. 7 is a view showing an alteration to an inner position of an experimental apparatus, which is simplified from the evaporating apparatus in accordance with this embodiment, for use in Experiment 2;

FIG. 8 a view for explaining a film forming state in the Experiment 2; and

FIG. 9 is a view for explaining a relationship of a gap G, a height T, a thickness D of each partition wall and a distance E from a center position of each vapor deposition source to a center position of each partition wall.

### EXPLANATION OF CODES

10: Evaporating apparatus
100: First processing chamber
110, 110a ˜110f: Blowing devices
120: Partition wall
130: Stage
140: QCM
200: Second processing chamber
210, 210a ˜210f: Vapor deposition sources
220, 220a ˜220f: Connection pipes
Op: Blowing opening

### BEST MODE FOR CARRYING OUT THE INVENTION

Hereinafter, embodiments of the present invention will be described in detail with reference to the accompanying drawings. Like reference numerals denote like parts through the whole document, and redundant description will be omitted.

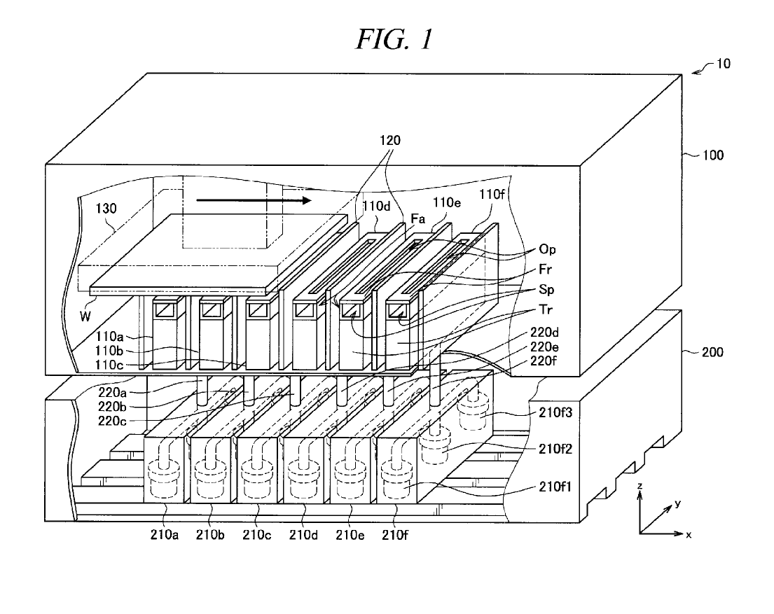

First, an evaporating apparatus in accordance with an embodiment of the present invention will be described with reference to FIG. 1, which provides a perspective view showing major components of the evaporating apparatus. The following description is provided for the example case of manufacturing an organic EL display by consecutively depositing 6 layers including an organic layer in sequence on a glass substrate (hereinafter simply referred to as “substrate”) by using the evaporating apparatus in accordance with the present embodiment.

(Evaporating Apparatus)

The evaporating apparatus 10 includes a first processing chamber 100 and a second processing chamber 200. The first processing chamber 100 has a rectangular parallelepiped shape and incorporates first to sixth blowing devices 110a to 110f therein. Inside the first processing chamber 100, film forming processes are consecutively performed on a substrate W by gas molecules blown off from the six blowing devices 110.

Each blowing device 110 has a length approximately equal to a width of the substrate W, and they have the same shape and configuration. These six blowing devices 110 having the same shape are arranged in parallel to each other at a same distance therebetween such that their lengthwise directions become substantially perpendicular to the advancing direction of the substrate W.

Each blowing device 110 has a buffer space Sp for temporarily storing a vaporized film forming material in its upper portion and a transport mechanism Tr for transporting the vaporized film forming material in its lower portion. A top surface of each blowing device 110 is closed by a frame Fr. The frame Fr is screw-fixed in its peripheral portion. Formed at the center of the frame Fr is a slit-shaped opening having a width of about 1 mm as a blowing opening Op which serves to blow off the film forming material stored in the buffer space Sp.

Installed between each of blowing devices 110 are seven sheets of partition walls 120 for respectively separating the adjacent blowing devices 110. The seven sheets of the partition walls 120 are flat plates having the same shape and are equally distant from facing surfaces Fa of the adjacent blowing devices 110, with the partition walls 120 arranged in parallel to each other at a same distance. Further, a side surface of each partition wall 120 facing the surface Fa of the adjacent blowing device 110 is larger in size than the surface Fa of the adjacent blowing device 110. In this way, the blowing devices 110 are respectively separated by the seven sheets of the partition walls 120, whereby it is prevented that gas molecules of the film forming materials blown off from the blowing opening Op of each blowing device 110 are mixed with gas molecules blown off from the blowing opening Op of the adjacent blowing device 110.

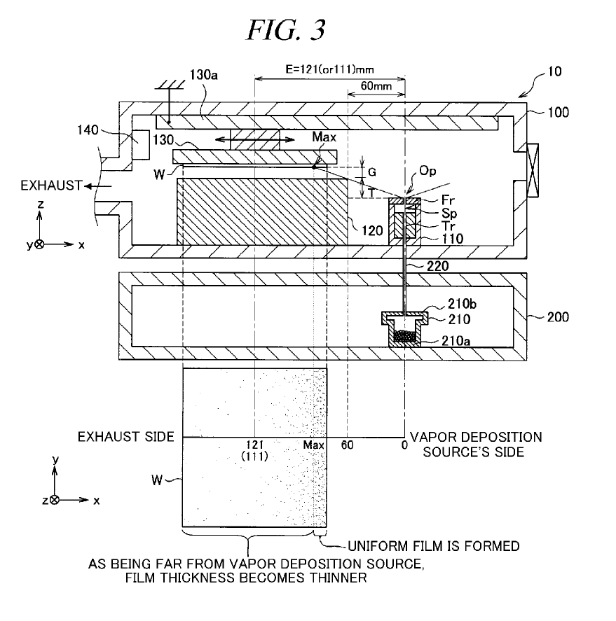

The substrate W is electrostatically attracted and held on a stage 130 slidably fixed to a sliding mechanism 130a in a ceiling portion of the first processing chamber 100 as illustrated in FIG. 3 and slides in an X-axis direction along a ceiling surface of the first processing chamber 100.

Installed in the first processing chamber 100 is a QCM (Quartz Crystal Microbalance) 140 as illustrated in FIG. 3. Below, the simple principle of the QCM will be explained.

In case that a density, an elastic modulus, a size or the like of a quartz vibrator body are varied equivalently by adhering a substance to the surface of a quartz vibrator, there occurs a variation of an electrical resonance frequency f, which is indicated by the following equation, due to the piezoelectric property of the vibrator.

f=½t(√C/ρ)

(t: thickness of a quartz piece, C: elastic constant, ρ: density)

By using this phenomenon, an infinitesimal quantity of deposits is measured quantitatively based on the variation of the resonance frequency of the quartz vibrator. A general term for the quartz vibrator designed as described is QCM. As can be seen from the equation, a change of the frequency is deemed to be determined based on a change of the elastic constant dependent on the adhered substance; and a thickness dimension of the adhered substance calculated in terms of the quartz density. Thus, the change of the frequency can be calculated in terms of the weight of the deposits.

The second processing chamber 200 has a substantially rectangular parallelepiped shape and also is provided with prominent portions and recess portions at its bottom portion. The second processing chamber 200 includes first to sixth vessels 210a to 210f therein, and three vapor deposition sources are installed in each vessel 210. For example, installed in the sixth vessel 210f are vapor deposition sources 210f1, 210f2 and 210f3. These vapor deposition sources have the same shape and configuration, and are connected with the first to sixth blowing devices 110a to 110f via six connection pipes 220a to 220f, respectively.

Installed at the respective connection pipes 220a to 220f outside the second processing chamber (in the atmosphere) or inside of the second processing chamber (in a vacuum state) are non-illustrated valves. By manipulating the opening/closing of each valve, it is controlled whether each film forming material (gas molecules) is supplied into the first processing chamber 100 or not.

Accommodated in the vapor deposition sources are different kinds of film forming materials as film forming source materials. By heating the respective vapor deposition sources to a high temperature in the range from about 200° C. to about 500° C., such different kinds of film forming materials are vaporized.

Supplied into each vapor deposition source is a nonreactive gas (e.g., an Ar gas) from non-illustrated gas supply sources. The supplied nonreactive gas functions as a carrier gas which carries organic molecules of the film forming materials vaporized from the respective vapor deposition sources to the blowing devices 110 through the connection pipes 220.

In each vapor deposition source, a heater is buried in its bottom wall and another heater (not illustrated either) is buried in its side wall. Based on a signal outputted from the QCM 140 installed in the first processing chamber 100, a generation rate of gas molecules of each film forming material can be calculated, and based on the obtained generation rate, a voltage to be applied to the heaters buried in the bottom wall and the side wall can be obtained.

Here, if based on deceleration that an adhesion coefficient decreases with the increase in a temperature, the number of the gas molecules physically adhered to a connection pipe or the like decreases with the increase of the temperature. By using this principle, a temperature of the heater buried in the side wall is set to be higher than that of the heater buried in the bottom wall. In this way, by setting the temperature of the vapor deposition source's other portions to be higher than the temperature of the vicinity of the vapor deposition source's portion where the film forming material is accommodated, the number of the gas molecules adhered to the vapor deposition source 210 or the connection pipe 220 can be reduced while the gas molecules are being flown toward the blowing device 110 after the film forming materials are vaporized. Accordingly, a greater amount of gas molecules can be blown off from the blowing device 110 and adhered to the substrate W.

Moreover, the insides of the first and second processing chambers 100 and 200 can be depressurized to preset vacuum levels by a non-illustrated exhaust system.

The substrate W is moved by the sliding mechanism 130a from the first blowing device 110a to the sixth blowing device 110f at a preset speed while being located slightly above each of the blowing devices 110a to 110f. As a result, different films are formed on the substrate W in six layers depending on the film forming materials blown off from the respective blowing devices 110a to 110f. Below, specific operation of the evaporating apparatus 10 during this 6-layer consecutive film forming process will be explained.

(6-Layer Consecutive Film Forming Process)

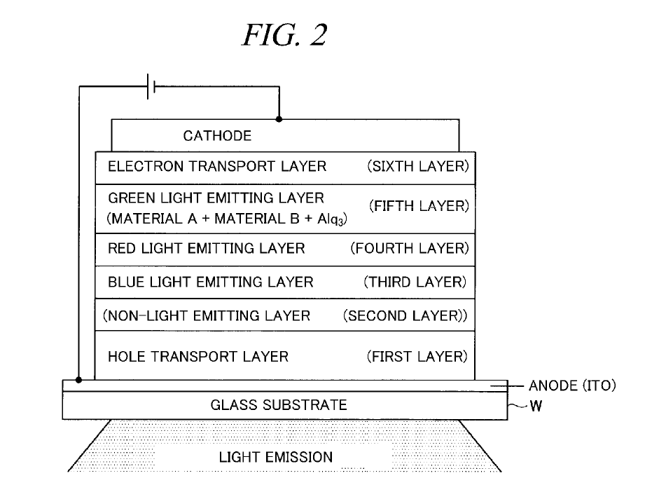

FIG. 2 illustrates the state of each layer deposited on the substrate W as a result of performing the 6-layer consecutive film forming process by using the evaporating apparatus 10. First, while the substrate W is being moved above the first blowing device 110a at a certain speed, a film forming material blown off from the first blowing device 110a is adhered to the substrate W, so that a hole transport layer as a first-layer is formed on an transparent electrode made of ITO (Indium Tin Oxide) of the substrate W.

In this manner, the substrate W is moved above the first to sixth blowing devices 110a to 110f in sequence. As a result, the hole transport layer, a non-light emitting layer, a light emitting layer and an electron transport layer are formed on the ITO of the substrate W by vapor deposition. Accordingly, 6 organic layers are consecutively formed on the substrate W within the same chamber.

(Shape and Arrangement Position of a Partition Wall)

As stated above, if a plurality of different thin films are consecutively formed on the substrate W by installing the plurality of vapor deposition sources 210 in one processing chamber and adhering the film forming molecules vaporized by each vapor deposition source 210 onto the substrate W, it is deemed that the film forming molecules vaporized from the adjacent vapor deposition sources 210 are mixed with each other and a film quality of each layer may be deteriorated.

Therefore, as stated above, each partition wall 120 has the side surface larger than the facing surface Fa of the adjacent blowing device, whereby it is possible to prevent the film forming molecules blown off from each blowing opening Op from crossing each partition wall 120 and flying toward the adjacent blowing opening Op (i.e., it is possible to prevent a cross-contamination).

Further, in this way, by optimizing a height and a thickness of the partition wall 120 formed in a flat-plate shape having the side surface larger than the facing surface of the blowing device, a distance (gap) between the top surface of the partition wall and the substrate W, and an arrangement position of the partition wall 120, it is possible to reduce the greater number of the film forming molecules (i.e., contaminants) crossing each partition wall 120 and flying toward the adjacent blowing opening Op.

(Experiment 1 for Optimizing a Shape and an Arrangement Position of a Partition Wall)

Accordingly, the inventor of the present invention repeatedly conducted the following experiment in order to optimize a shape and an arrangement position of a partition wall 120. First, processing conditions for the experiment will be explained. FIG. 3 illustrates an experimental apparatus, which is simplified from an evaporating apparatus in accordance with the present embodiment. As illustrated, the inventor prepared the experimental apparatus in which a single blowing device 110 and a single partition wall 120 were installed inside of a first processing chamber 100 of the evaporating apparatus 10 and a vapor deposition source 210 were installed inside of a second processing chamber 200 thereof. Further, the inventor made the blowing device 110 connected to the vapor deposition source 210 through a connection pipe 220. Accommodated in the vapor deposition source 210 was 0.1 g of an organic material of Alq₃ (aluminum-tris-8-hydroxyquinoline) serving as a film forming material.

Furthermore, the inventor allowed 0.5 sccm of an Ar gas as a carrier gas to be supplied to the vicinity of the blowing opening Op in the blowing device 110. Moreover, the inventor allowed a high voltage HV of 4 kV to be applied to a stage 130 in order to electrostatically attract and hold the substrate W thereon, and also allowed an Ar gas of 40 Torr to be supplied to a backside of the substrate W in order to radiate heat of the stage by increasing a back pressure BP of the substrate W.

Further, the inventor installed the partition wall 120 such that a distance in an X-axis direction from a center axis of the blowing device 110 to a side surface of the partition wall 120 facing toward the blowing device 110 was set to be 60 mm and a height T (distance in a Z-axis direction) from the blowing opening Op to a top surface of the partition wall 120 was set to be 7 mm. In this state, the inventor controlled the vapor deposition source 210 to be heated to a temperature of 200° C. and then controlled the stage 130 to be moved up and down so as to set a gap G between the stage 130 and the top surface of the partition wall 120 to be 6 mm, and also controlled the substrate W to be moved by sliding a sliding mechanism 130a of the stage 130 so as to set a distance in the X-axis direction from a center axis of the blowing device 110 to a center axis of the substrate W to be 121 mm.

Thereafter, the inventor set a bottom portion 210a of the vapor deposition source 210 to have a temperature of 320° C. and set each of an upper portion 210b of the vapor deposition source 210, the connection pipe 220 and the blowing device 110 to have a temperature of 340° C. and then checked that each of the temperatures reached each of the preset temperatures.

The Alq₃ accommodated in the vapor deposition source 210 is vaporized into film forming molecules and is discharged from the blowing opening Op into the first processing chamber 100 passing through from the connection pipe 220 to a transport mechanism Tr. Then, the discharged film forming molecules of Alq₃ radially diffuse while traveling in a straight line by a pressure difference between the inside and the outside of the blowing opening Op, and are adhered to a bottom surface of the substrate W.

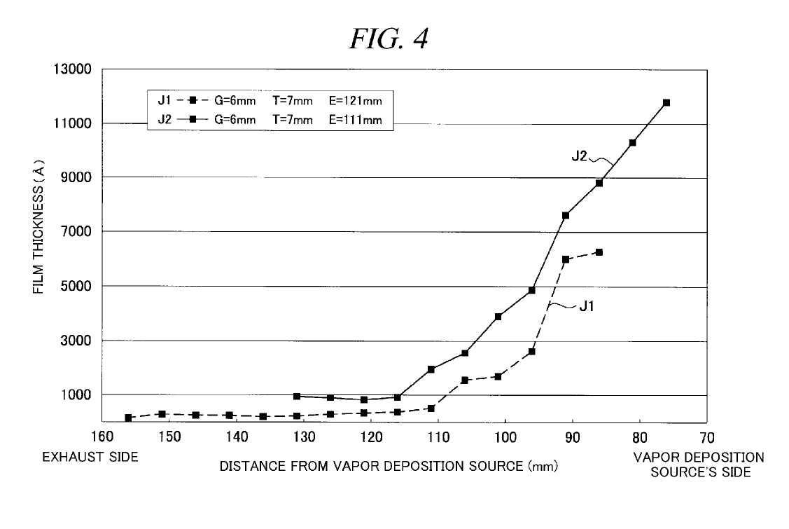

Then, the film forming material (film thickness) adhered to the bottom surface of the substrate W is measured by a film thickness measuring device. As an example of the film thickness measuring device, there can be employed an interferometer (e.g., a laser interferometer) for detecting a film thickness of a target object by, e.g., irradiating light outputted from a light source onto a top surface and a bottom surface of a film formed on the target object and observing and analyzing an interference fringe generated by a difference in optical paths of two reflected beams or a method of calculating a film thickness based on spectrum information of irradiated light having a broadband wavelength. A result thereof is shown by a graph J1 in FIG. 4. Thereafter, the inventor allowed the substrate W to be moved by sliding the sliding mechanism 130a of the stage 130 such that a distance in the X-axis direction from the center axis of the blowing device 110 to the center axis of the substrate W is set to be 111 mm, and then carried out the same experiment. A result thereof is shown by a graph J2 in FIG. 4.

(Result of Experiment 1)

As a result of the experiment, as can be seen from the bottom surface of the substrate W illustrated in the underside of FIG. 3, a good quality film is uniformly formed on a surface of the vapor deposition source's side from a position Max in the X-axis direction where the film forming molecules radially blown off from the blowing opening Op are adhered to the substrate W when they fly farthest away. Furthermore, as illustrated in FIG. 4, it can be seen that on the surface in the range from the position Max to about the center of the substrate W, the film becomes thinner as it is far from the blowing device 110. Meanwhile, the film thickness is substantially uniform on a surface of an exhaust side from the vicinity of the center of the substrate W, and it is such an extent that the film is slightly formed.

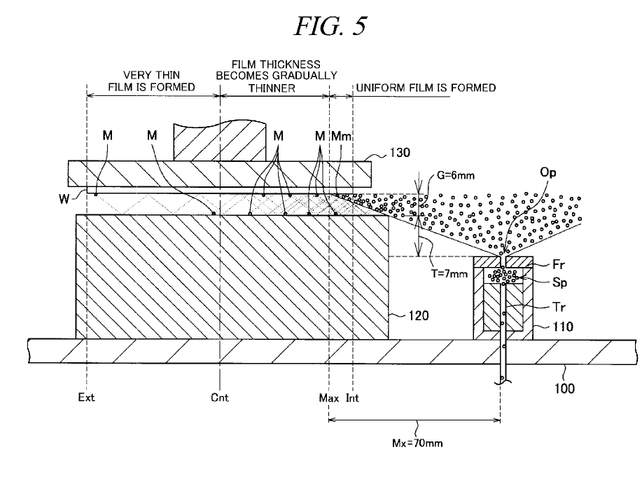

Based on this result, the inventor conceived as follows. As illustrated in FIG. 5, the film forming molecules of Alq₃ blown off from the blowing opening Op are radially diffused. At this time, each film forming molecule travels in a straight line. In a radial area where the film forming molecules blown off from the blowing opening Op are diffused, in order for a film forming molecule Mm flying straightly along the outermost side of the radial area to be adhered to the substrate, a longest flight distance of the film forming molecule Mm is needed to be shorter than a mean free path of the film forming material of Alq₃. Here, in case that a gap G between the substrate W and the upper portion of the partition wall is 6 mm; a height T from the blowing opening Op to the top surface of each partition wall 120 is 7 mm; and a distance Mx in an X-axis direction from the blowing opening Op to a position where the film forming molecule Mm is adhered is 70 mm, a longest flight distance of 71.2 (=(Mx²+(G+T)²)^{1/2}) can be obtained.

Meanwhile, a mean free path (MFP) can be expressed by the following equation as described in Vacuum Technology Reference Table for General Use from Vacuum Science and Technology Lesson 12 (Nikkan Kogyo Shimbun, 1965).

MFP=3.11×10⁻²⁴×T/P(δ)×1000(mm)

(Here, T: temperature K, P: pressure Pa, δ: molecule diameter m)

For example, as described in the above document (Vacuum Technology Reference Table for General Use), a molecule diameter of an Ar gas is 3.67×10⁻¹⁰ m, so that a mean free path MFP of the Ar gas is 1323.4 mm at a temperature T of 573.15 K and a pressure of 0.01 Pa.

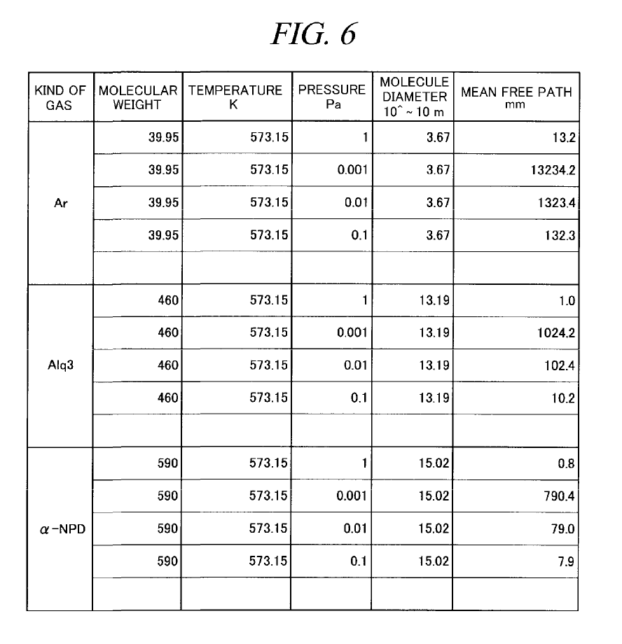

FIG. 6 provides a table showing mean free paths of spherical film forming molecules of an Ar gas, Alq₃ and α-NPD. It can be seen from the table that the mean free path of the gas molecule depends on a pressure. Based on this table, the inventor found that if an internal pressure of the evaporating apparatus 10 is set to be equal to or less than 0.01 Pa, the mean free paths of the Ar gas, Alq₃, α-NPD are 1323.3 mm or more, 102.4 mm or more and 79 mm or more, respectively, so that the film forming molecule Mm having the longest flight distance of 71.2 mm can be adhered to the substrate without fail during flying. As a result, it is found that on the surface of the substrate W in the range from an end portion Int of the vapor deposition source's side (see FIG. 5) to the position Max where the film forming molecule Mm having the longest flight distance reaches, an organic film is uniformly formed. Further, as stated above, since a mean free path depends on a pressure, if, for example, the pressure is set to be less than 0.01 Pa, the mean free path becomes longer. In this manner, by controlling a pressure, the film forming molecule Mm having a longest flight distance can surely reach the substrate.

Here, according to the disclosure of a book titled “Thin Film Optics” (published by Murata Seishiro, Maruzen Inc., the 1^{st} print on Mar. 15, 2003 and the 2^{nd} print on Apr. 10, 2004), vaporized molecules that have reached the substrate are not adhered to the substrate W and accumulated thereon just as they are in a manner that they are fallen and stacked to form a film, but a part of them is reflected and rebounded into the vacuum. Further, some of the molecules adhered on the surface of the substrate keep moving on the surface; some of them are bound again into the vacuum; and some of them are caught in sites on the substrate W to form a film.

Accordingly, some of the film forming molecules adhered to the substrate W are rebounded and travel forward while being reflected in the gap G between the substrate W and the upper portion of the partition wall, and then adhered again to certain positions on the substrate W and the top surface of the partition wall. Based on such an behavior of the molecule, the inventor found that on the surface in the range from the arriving position Max of the film forming molecule Mm having the longest flight distance to the vicinity Cnt of the center of the substrate W, as the molecule was far from the vapor deposition source, the film thickness became gradually thinner as illustrated in the underside of FIG. 3 and in FIG. 4, since a ratio of the molecules traveling in a straight line while being reflected in the gap G between the substrate W and the upper portion of the partition wall became smaller than a ratio of a molecule M adhered to any one of the substrate W and the upper portion of the partition wall.

Furthermore, the inventor found that the film forming molecules were not readily adhered to the surface in the range from the vicinity Cnt of the center of the substrate W to an end portion Ext of the exhaust side of the substrate W as illustrated in the underside of FIG. 3 and in FIG. 4, since almost all of the film forming molecules were adhered to substrate W in the range from the end portion Int of the vapor deposition source's side to the vicinity Cnt of the center of the substrate W and thus there were few molecules M going forward while being reflected in the gap G between the substrate W and the upper portion of the partition wall in the range from the vicinity Cnt of the center of the substrate W to the end portion Ext of the exhaust side of the substrate W.

(Experiment 2)

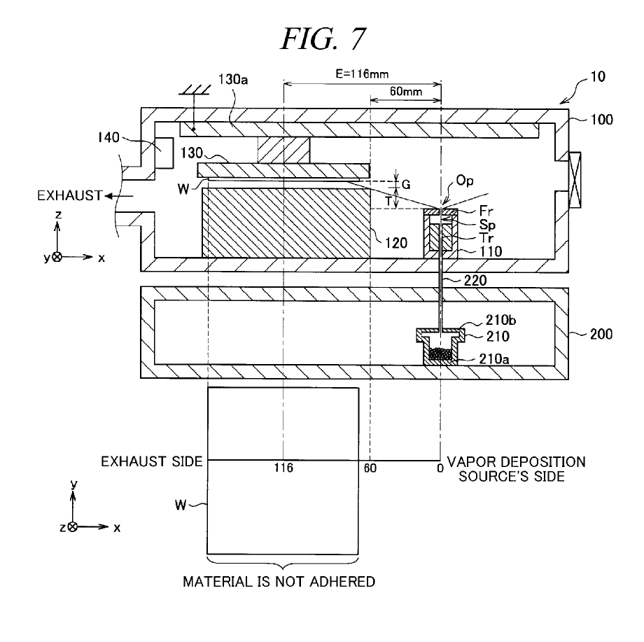

In order to further prove a straight travelling property of a film forming molecule, the inventor carried out an experiment again in a state that the gap G was changed from 6 mm to 2 mm and a position of the stage 130 was changed so as to set a distance in an X-axis direction from the center of the blowing device 110 to the center of the substrate W to be 116 mm, as illustrated in FIG. 7.

(Result of Experiment 2)

After the experiment, the inventor controlled a UV light to be irradiated onto the entire surface of the substrate W but a light hν was not radiated from any place. If film forming molecules of Alq₃ was adhered to the substrate W, the film forming molecule M was excited by energy of the irradiated UV light and then the light hν was radiated when the film forming molecule M returned to a ground state, the inventor concluded that in case that the gap G was changed from 6 mm to 2 mm and the position of the stage 130 was changed so as to set the distance in the X-axis direction from the center of the blowing device 110 to the center of the substrate W to be 116 mm, the material was not adhered to the substrate W.

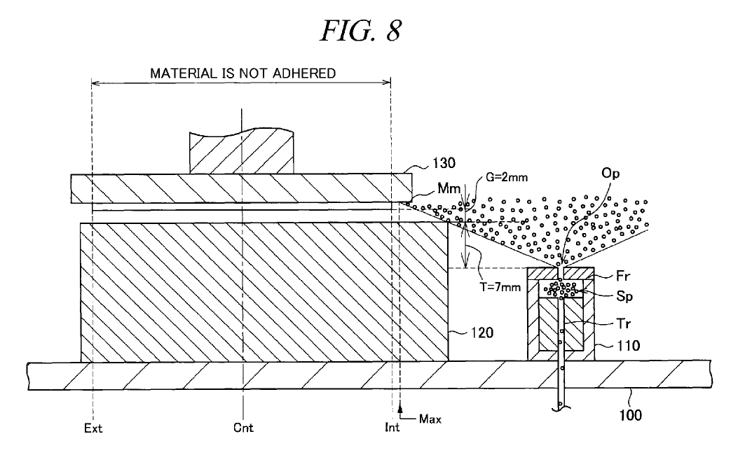

In case that the gap G was changed from 6 mm to 2 mm, the inventor considered that the reason why the film forming molecule is not adhered to the substrate W is because “the film forming molecule has a straight travelling property.” To be specific, as illustrated in FIG. 8, the inventor concluded that the reason why the film forming material was not adhered to the substrate W was because, among the film forming molecules blown off from the blowing opening Op, the film forming molecule Mm with a longest flight distance traveling in a straight line to the target object without being blocked by the partition wall 120 had an arriving position Max which is closer to the blowing device rather than to the end portion Int of the substrate W on the blowing device's side; because, among the film forming molecules adhered to a certain position, an amount of the film forming molecules M separated from a adhesion position and entering the gap G between the substrate W and the top surface of the partition wall is very small due to a very small size of the gap G; and because there exist few molecules M traveling in a straight line in the gap while reflecting the substrate W and the top surface of the partition wall since the amount of the film forming molecules entering the gap G between the substrate W and the top surface of the partition wall is very small.

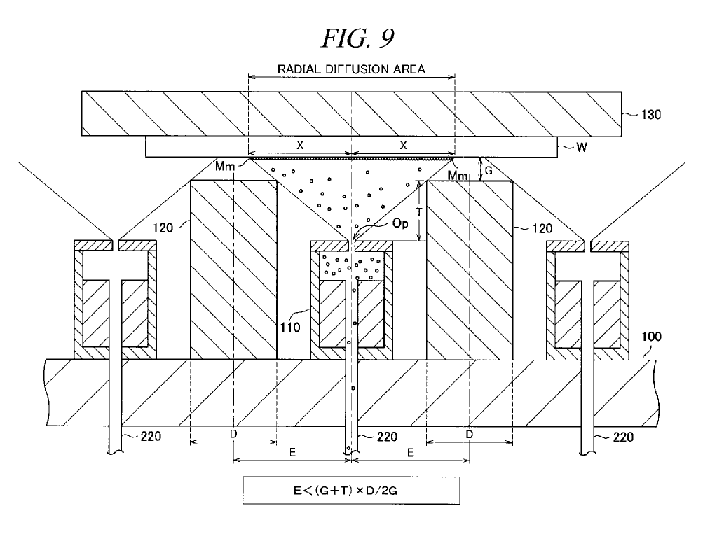

From the above-stated experiments, the inventor found an optimum relationship with respect to the shape and the arrangement position of the partition wall 120. That is, as illustrated in FIG. 9, the respective film forming molecules blown off from the blowing opening Op radially travel in a straight line. In the area where the film forming molecules are radially diffused, a film is uniformly formed on the substrate W. Some of the molecules adhered to the substrate W are separated from the substrate W, fly again and enter the gap G between the substrate W and the top surface of the partition wall. The amount of the molecules entering the gap G between the substrate W and the top surface of the partition wall varies depending on the size of the gap G. In case that the gap G has a size of 2 mm, there exist few molecules entering the gap G between the substrate W and the top surface of the partition wall, so that there does not occur a problem of cross-contamination that film forming molecules blown off from each blowing opening Op are mixed with film forming molecules blown off from the adjacent blowing opening Op and thus a film quality becomes deteriorated. Accordingly, it is desirable that the gap G between the substrate W and the top surface of the partition wall is equal to or less than about 2 mm.

Meanwhile, even in case that gap G has a size of about 6 mm or less, if the shape and the arrangement position of the partition wall 120 are optimized so as to satisfy the following two conditions, the cross-contamination is not problematic. Further, the following two conditions are needed to be satisfied even if the gap G between the substrate W and the upper portion of the partition wall has a size of about 2 mm or less.

A first condition is that a longest flight distance of a film forming material is shorter than a mean free path of the film forming material. According to this condition, among film forming molecules blown off from each blowing opening Op and diffused into a radial diffusion area, all the film forming molecules which are not blocked by each partition wall 120 can reach a substrate W without fail while flying in a space of the first processing chamber 100. Therefore, it is possible to uniformly form a good quality film on the substrate W.

Further, a second condition is that an arriving position of the film forming material Mm with the longest flight distance traveling in a straight line to the substrate W without being blocked by each partition wall 120 (a distance X in an X-axis direction from a center position of the blowing device 110 to an arriving position of the film forming material Mm) is shorter than a position of the substrate W equally distant from the adjacent blowing device 110 (a distance E in the X-axis direction from the center position of the blowing device 110 to a center position of the adjacent partition wall 120).

According to this condition, most of the film forming molecules blown off from each blowing opening Op reach within a radial diffusion area and are not mixed with the film forming molecules blown off from the adjacent blowing opening Op. Accordingly, it is possible to consecutively form films having desired properties on the substrate W only with the film forming molecules blown off from each blowing opening Op.

The second condition can be expressed by the following inequality.

E>X (1)

Here, in case that a thickness of the partition wall 120 is D, the following equation is derived on the basis of proportional relationships within a triangle.

(G+T)/T=X/(E−D/2) (2)

If the equation (2) is applied to the inequality (1), the following inequality is derived.

X=(G+T)(E−D/2)/T<E (3)

Further, the inequality (3) is modified as follows.

E<(G+T)DG/2 (4)

The gap G between each partition wall 120 and the substrate W, the height T from each blowing opening Op to the top surface of each partition wall 120, the thickness D of each partition wall 120 and the distance E from the center position of each vapor deposition source 210 (blowing device 110) to the center position of each partition wall can be determined so as to satisfy the inequality (4) obtained as stated above. Accordingly, the cross-contamination can be reduced to a level which is not problematic. Therefore, it is possible to consecutively form organic films in the same processing chamber while maintaining properties of each layer in good condition.

As a result, it is possible to reduce contaminants adhered to the substrate W during transfer in order to consecutively form the films in the same processing chamber. Accordingly, by reducing the number of contaminants adhered onto the substrate W while preventing the cross-contamination, it is possible to increase a controllability for an energy interface and lower an energy barrier. As a result, a luminous intensity (luminance) of an organic EL device can be improved. Further, by consecutively performing the film forming processes on the substrate W in the same processing chamber, it is possible to reduce a footprint.

Moreover, in the above-described embodiment, the size of the glass substrate capable of being processed by the evaporating apparatus 10 is about 730 mm×920 mm or greater. For example, the evaporating apparatus 10 is capable of consecutively carrying out the film formation on G4.5 substrates having a size of about 730 mm×920 mm (in-chamber size: about 1000 mm×1190 mm) or G5 substrates having a size of about 1100 mm×1300 mm (in-chamber size about 1470 mm×1590 mm). Further, the evaporating apparatus 10 is also capable of carrying out the film formation on a wafer having a diameter of, e.g., about 200 mm or 300 mm. That is, a target object on which the film formation is performed may include a glass substrate and a silicon wafer.

In the above-described embodiment, the operations of the respective components are interrelated and can be substituted with a series of operations in consideration of such interrelation. By the substitution, the embodiment of the evaporating apparatus can be used as an embodiment of an evaporating method.

The above description of the present invention is provided for the purpose of illustration, and it would be understood by those skilled in the art that various changes and modifications may be made without changing technical conception and essential features of the present invention. It shall be understood that all modifications and embodiments conceived from the meaning and scope of the claims and their equivalents are included in the scope of the present invention.

For example, in the evaporating apparatus 10 in accordance with the above-described embodiment, an organic EL material in the form of powder (solid) is used as the film forming material, and an organic EL multi-layer film forming process is performed on the substrate W. However, the evaporating apparatus in accordance with the present invention can also be employed in a MOCVD (Metal Organic Chemical Vapor Deposition) method for depositing a thin film on a target object by decomposing a film forming material vaporized from, e.g., a liquid organic metal on the target object heated up to about 500° C. to 700° C. As described, the evaporating apparatus in accordance with the present invention may be used as an apparatus for forming an organic EL film or an organic metal film on the target object by vapor deposition by using an organic EL film forming material or an organic metal film forming material as a source material.

Furthermore, the evaporating apparatus in accordance with the present invention may or may not have a configuration in which the blowing device 110 (blowing opening Op) is connected with the vapor deposition source 210 through the connection pipe 220, and may have a configuration, for example, in which the film forming molecules are discharged from the blowing opening provided at the vapor deposition source 210 without the blowing device 110. Moreover, in the evaporating apparatus in accordance with the present invention, the first processing chamber 100 and the second processing chamber 200 do not have to be configured as separate bodies and may be configured such that consecutive film formation processes are performed in one processing chamber.

1. An evaporating apparatus for performing a film forming process on a target object by a vapor deposition in a processing chamber, the apparatus comprising:
a plurality of vapor deposition sources, each accommodating a film forming material and vaporizing the accommodated film forming material;
a plurality of blowing devices, each being connected with each of the vapor deposition sources and each blowing device having a blowing opening and blowing off each film forming material vaporized from each of the vapor deposition sources through the blowing opening; and
one or more partition walls disposed between adjacent blowing devices among the plurality of blowing devices, for separating the adjacent blowing devices,
wherein the one or more partition walls are arranged so as to satisfy two conditions:
among film forming molecules of the film forming material radially diffused from a blowing opening provided at the adjacent blowing device, a film forming molecule with a longest flight distance traveling in a straight line to the target object without being blocked by each partition wall has an arriving position which is closer to the blowing opening that blows off the film forming molecule with the longest flight distance than to a position on the target object equally distant from the adjacent blowing devices, and
the longest flight distance of the film forming molecule is shorter than a mean free path of the film forming molecule.

2. The evaporating apparatus of claim 1, wherein the plurality of blowing devices has the same shape and is arranged in parallel to each other at a same distance therebetween, and
the one or more partition walls have the same shape, and are equally distant from the adjacent blowing devices and arranged in parallel to each other at a same distance between the adjacent blowing devices.

3. The evaporating apparatus of claim 2, wherein each surface of the partition wall facing the blowing device adjacent to each partition wall is larger than a surface of the adjacent blowing device.

4. (canceled)

5. The evaporating apparatus of claim 1, wherein an internal pressure of the processing chamber is equal to or less than about 0.01 Pa.

6. The evaporating apparatus of claim 1, wherein each of the partition walls is arranged such that relationships of a gap G between each partition wall and the target object, a height T from each blowing opening to a top surface of each partition wall, a thickness D of each partition wall and a distance E from a center position of each vapor deposition source to a center position of each partition wall satisfy: E<(G+T)×D/2G.

7. The evaporating apparatus of claim 1, wherein the apparatus is a substrate processing apparatus for forming any one of an organic EL film and an organic metal film on the target object by using an organic EL film forming material or an organic metal film forming material as an organic material.

8. An evaporating method for performing a film forming process on a target object by a vapor deposition in a processing chamber, the method comprising:
vaporizing each of film forming materials accommodated in each of vapor deposition sources;
blowing off each film forming material vaporized from each vapor deposition source through an blowing opening of each blowing device connected with each vapor deposition source; and
consecutively forming films on a target object with the vaporized film forming materials while preventing the film forming materials blown off from respective blowing openings from crossing each partition wall and flying to adjacent blowing openings by using one or more partition walls disposed between the adjacent blowing devices among the plurality of blowing devices, for separating the adjacent blowing devices,
wherein the one or more partition walls are arranged so as to satisfy two conditions:
among film forming molecules of the film forming material radially diffused from a blowing opening provided at the adjacent blowing device, a film forming molecule with a longest flight distance traveling in a straight line to the target object without being blocked by each partition wall has an arriving position which is closer to the blowing opening that blows off the film forming molecule with the longest flight distance than to a position on the target object equally distant from the adjacent blowing devices, and
the longest flight distance of the film forming molecule is shorter than a mean free path of the film forming molecule.

9. (canceled)

10. (canceled)

11. The evaporating method of claim 8, wherein the one or more partition walls are arranged such that relationships of a gap G between each partition wall and the target object, a height T from each blowing opening to a top surface of each partition wall, a thickness D of each partition wall and a distance E from a center position of each vapor deposition source to a center position of each partition wall satisfy an inequality of E<(G+T)×D/2G.
